(19) United States
(12) Patent Application Publication
(10) Pub. No.: US 2017/0155045 A1
(43) Pub. Date: Jun. 1, 2017

(54) Method to Manufacture Highly Conductive Vias and PROM Memory Cells by Application of Electric Pulses

(71) Applicants: Marius Orlowski, Pembroke, VA (US); Gargi Ghosh, Blacksburg, VA (US); Anshuman Verma, Blacksburg, VA (US)

(72) Inventors: Marius Orlowski, Pembroke, VA (US); Gargi Ghosh, Blacksburg, VA (US); Anshuman Verma, Blacksburg, VA (US)

(21) Appl. No.: 15/365,445

(22) Filed: Nov. 30, 2016

Related U.S. Application Data
(60) Provisional application No. 62/260,665, filed on Nov. 30, 2015.

(51) Int. Cl. H01L 45/00; H01L 27/24

(52) U.S. Cl. CPC H01L 45/1641; H01L 45/06; H01L 45/1233; H01L 45/1253; H01L 45/149; H01L 27/2463

(57) ABSTRACT

A memory device having a first array of first electrodes extending along a first direction made from a first material and a second array of second electrodes extending along a second direction made from a second material. An intersection defined by the first array and the second array, wherein each intersection of the first array and the second array defines a two-terminal resistive memory cell, said memory cell formed by a conductive path between said first and second electrodes.

### RELATED APPLICATIONS

This application claims the benefit of U.S. Provisional Application No. 62/260,665, filed Nov. 30, 2015, and herein incorporated by reference.

### STATEMENT REGARDING FEDERALLY SPONSORED RESEARCH & DEVELOPMENT

Not applicable.

### INCORPORATION BY REFERENCE OF MATERIAL SUBMITTED ON A COMPACT DISC

Not applicable.

### BACKGROUND OF THE INVENTION

Building nonvolatile memory (NVM) directly into a CMOS low-k/Cu interconnects would reduce latency in connectivity constrained computational devices and reduce the footprint of a chip by stacking memory on top of logic. NVM memory includes: i) random-access memory, and ii) programmable read-only memory (PROM). The present invention provides suitable embodiments for an integration of PROM compatible with manufacturing of CMOS back-end. The invention is also suitable for a realization of Field Programmable Gate Array (FPGA). FPGA is an integrated circuit designed to be configured by a customer or a designer after manufacturing—hence “field-programmable”. FPGAs contain an array of programmable logic blocks, and a hierarchy of reconfigurable interconnects that allow the blocks to be “wired together”, like many logic gates that can be inter-wired in different configurations. In this case programmed PROM cells become the one-time reconfigurable conductive connections between the metallization lines.

### BRIEF DESCRIPTION OF THE SEVERAL VIEWS OF THE DRAWINGS

In the drawings, which are not necessarily drawn to scale, like numerals may describe substantially similar components throughout the several views. Like numerals having different letter suffixes may represent different instances of substantially similar components. The drawings illustrate generally, by way of example, but not by way of limitation, a detailed description of certain embodiments discussed in the present document.

FIG. 1 depicts a BEOL and RRAM memory.

FIG. 2 shows how embodiments of the present invention may be implemented between metal lines of an integrated circuit.

FIG. 3 depicts the formation of an electrical conductor at a first transition voltage or current.

FIG. 4 depicts the formation of an electrical conductor at a second transition voltage or current.

FIGS. 5A and 5B provide a comparison of low dielectrics SiOC:H with SiC:H and SiCN:H.

### BRIEF SUMMARY OF THE INVENTION

In one embodiment, the present invention provides a device and method that builds nonvolatile memory (NVM) into a CMOS low-k/Cu interconnects to reduce latency in connectivity constrained computational devices. NVM memory includes random-access memory and programmable read-only memory (PROM).

In another embodiment, the present invention reduces the footprint of a chip by stacking memory on top of logic.

In another embodiment, the present invention provides suitable choices of materials for an integration of PROM compatible with manufacturing of CMOS back-end.

In other embodiments, the present invention provides back end of line (BEOL) metal-insulator-metal (MIM) structures having low-k dielectric properties.

In another embodiment of the present invention, a Cu electrode is used to form one or more conductors which may be permanent Cu filaments, that electrically connect metal lines.

In another embodiment of the present invention, the conductors cannot be ruptured due to their cylindrical shape.

In another embodiment of the present invention, conductor formation in SiC:H and SiCN:H is possible for a minimum compliance current I_{cc}.

In another embodiment of the present invention, the ON-Resistance is very low even at a low I_{cc}.

In another embodiment of the present invention, the conductor has a two-stage transition.

In another embodiment of the present invention, the first transition is from 200 MΩ to 150 kΩ and the second transition is from 150 kΩ to 10 Ω (ratios 10³ and 10⁴, respectively).

In another embodiment of the present invention, the two-stage transition of the conductor does not depend on bias polarity.

In another embodiment of the present invention, the two-stage transition of the conductor used to tune the device by choice of I_{cc} level.

In other embodiments, the present invention uses porous dielectric materials to form highly resistive conductors such as Cu filaments.

In other embodiments, the present invention uses highly resistive Cu filaments to realize a PROM memory or FPGA capability.

In other embodiments, the present invention uses highly resistive Cu filaments to create self-aligned electric vias by voltage/current pulses or voltage/current ramps.

It is to be understood that both the foregoing general description and the following detailed description are exemplary and explanatory only and are not restrictive of the invention, as claimed.

### DETAILED DESCRIPTION OF THE INVENTION

Detailed embodiments of the present invention are disclosed herein; however, it is to be understood that the disclosed embodiments are merely exemplary of the invention, which may be embodied in various forms. Therefore, specific structural and functional details disclosed herein are not to be interpreted as limiting, but merely as a representative basis for teaching one skilled in the art to variously employ the present invention in virtually any appropriately detailed method, structure, or system. Further, the terms and phrases used herein are not intended to be limiting, but rather to provide an understandable description of the invention.

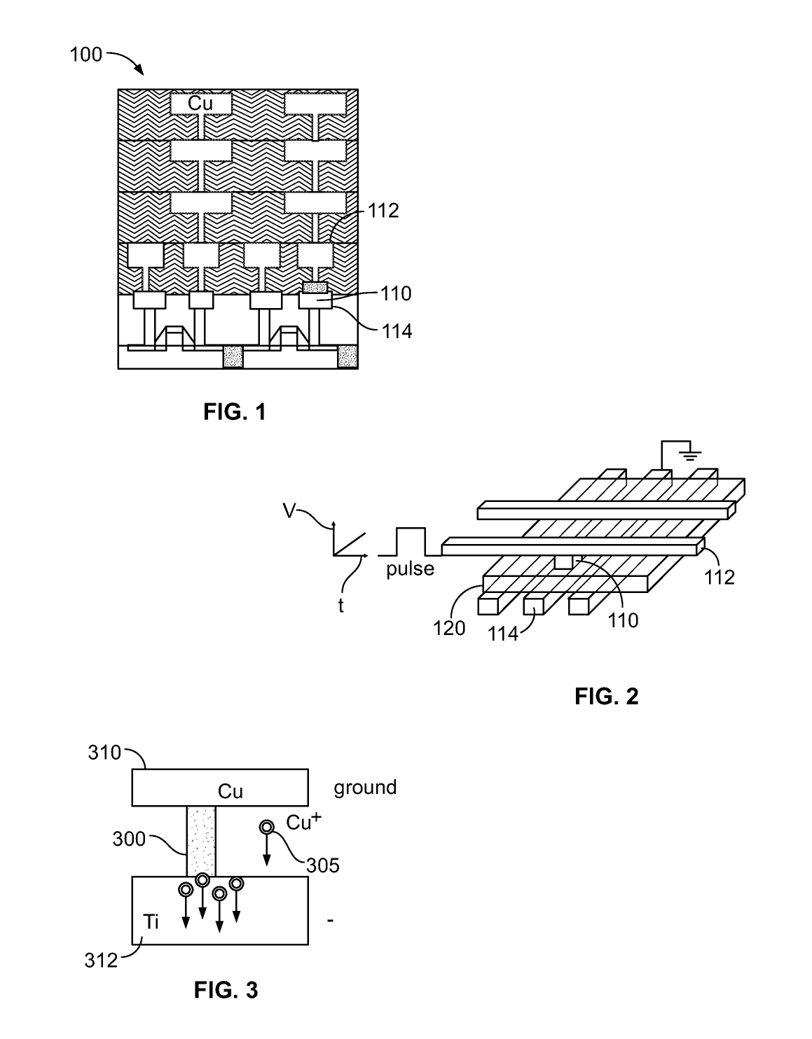

As shown in FIGS. 1 and 2, in one embodiment, the present invention provides in the metallization backend of integrated circuit 100 an electrical connection or conductor 110 located between a first metal line 112, which may act as a first electrode, and a second metal line 114, which may act as a second electrode. In a preferred embodiment, electrical connection 110 may be a Cu filament. In another preferred embodiment, first electrode 112 may be made of a first material and adapted to function as a terminal. More than one electrode may be used to form an array of electrodes extending along a first direction. Second electrode 114 may be made of a second material and adapted to function as a terminal. More than one electrode may be used to form an array of electrodes that extend along a second direction.

In addition, an insulator layer 120, such as a dielectric, may be disposed between the first and the second electrode and/or the arrays of electrodes. The dielectric may be a low-k dielectric. The dielectric may also be comprised of silicon, oxygen, carbon, and hydrogen such as SiOC:H. The dielectric may also be a porous dielectric.

Applying a voltage or current to one of the electrodes creates an active electrode while the other electrode is grounded. The voltage or current causes ions consisting of the material of the ungrounded electrode or charged defects of the dielectric to form electrical connection 110 which may be in the form of a conductor such as a filament that electrically connects the electrodes.

In yet other embodiments, the powered electrode may be an active electrode such as copper, silver or nickel, or inert electrode such as platinum, iridium, tungsten, or rhodium. The grounded electrode may be inert metals such as platinum, iridium, tungsten, or rhodium. It should be noted that electrode 112 may be the active or ground electrode and that electrode 114 may also serve as the active or ground electrode depending upon the bias of the current or voltage is applied.

In yet other embodiments, the voltage or current causes the copper or silver or nickel ions to diffuse into the grounded electrode to form a filament that may be a cylinder-like shape.

In other embodiments, the piling and agglomoration of Cu ions, is a stochastic and a disorderly process. As a result, the cross section through the filament at different heights or locations will show different sizes of cross section. In the case of a perfect cone it would be a large circle at the base. This circle would get smaller along the filament and end up in a single point at the apex of the cone. In case of a cylinder the cross-section would be the same at every height. In a cylinder-like configuration, the cross section may be more or less the same along the filament. In case of a cone, the cross-section will vary strongly with the height.

In a preferred embodiment, the filament or conductive phase of the dielectric material is irreversible when a subsequent voltage or current is applied. In other applications, it may be reversible.

In yet other embodiments, the voltage or current causes charged point defects in the dielectric, such as oxygen vacancies. This creates a conductive phase of the dielectric material which electrically connects the two electrodes

In yet other embodiments, a first transition voltage is created by applying a voltage or current pulse to one of the electrodes to create an active electrode while the other electrode is grounded. The first transition voltage causes ions consisting of the material of the ungrounded electrode or charged point defects of the insulating material to form electrical conductor 110 which may be a filament or a phase change of the dielectric that electrically connects the electrodes. This electric connection has a first resistance that is substantially lower than that of the insulating layer 120.

In yet other embodiments, a second transition voltage is created by applying a voltage or current pulse to one of the electrodes to define the powered electrode while the other electrode is grounded. This electric connection has a second resistance that is less than said first resistance. The second transition voltage or current may be applied as a voltage or current pulse or as a linear voltage or current ramp.

In certain embodiments of the present invention, the electrical connection or conductive phase of the dielectric is irreversible after the first transition voltage is applied. In yet other embodiments of the present invention, the electrical connection or conductive phase of the dielectric is irreversible after the second transition voltage or current is applied. In yet other embodiments of the present invention, the electrical connection or conductive phase of the dielectric is only irreversible after the second transition voltage or current is applied. In yet other embodiments of the present invention, the electrical connection or conductive phase of the dielectric is only irreversible after both the first transition voltage or current is applied and the second transition voltage or current is applied. In still further embodiments of the present invention, the second resistance may be decreased by a factor that is approximately 1 to 2 orders of magnitude from that of the first resistance.

In other embodiments of the present invention, applying a voltage of current results in the formation of multiple electrical connections which may be in the form of one or more conductors which may be filaments. The implementation of this embodiment allows for the use of one active line (first electrode) that is powered and several lines (second electrodes) that may be grounded. Then the same pulse or ramp of voltage or current to the first electrode will create several connections (filaments) at the same time between the powered line and the grounded lines. In yet other embodiments, multiple filaments may be formed at different locations, and the filaments may be cylindrical filaments. In addition, the cylindrical filaments may be formed at different locations. Using this technique, the present invention uses highly conductive conductors such as Cu filaments to create self-aligned electric vias by voltage/current pulses or voltage/current ramps.

It has also been determined that the above described electrically defined vias, created by application of a voltage pulse or voltage ramp to one of the lines while the other is grounded, may have improved electromigration properties. This results from the conductive filament being anchored in the dielectric matrix.

In other specific embodiments of the present invention, capacitor-like MIM structures (Al/Ti/I/Cu), with dielectrics I=SiOC:H, SiC:H, SiCN:H, preferably 25 nm thick, may be used. The Ti/Al electrode may be used as the grounded electrode in some applications and a positive bias applied to the Cu electrode.

For SiOC:H devices, a sharp transition from R_{OFF}=200 MΩ to R_{ON}(1)=120 kΩ at threshold Vₛₑₜ(1)=0.9V-1.2 V was observed. When the set device is subsequently subjected to a linear voltage ramp, a secondary sharp set transition from R_{ON}(1)=120 kΩ to R_{ON}(2)=2-10Ω is observed at |Vₛₑₜ(2)|=1.0-1.3V as well as high compliance currents I_{cc}≈100 mA, independent of the bias polarity. R_{ON}(2) may be controlled by the level of I_{cc} (@I_{cc}≈10 mA R_{ON}(2)=34Ω).

Both transitions are irreversible and the low resistance states are stable. The first transition, in some circumstances, may be caused by formation of a Cu conductor 300 which may be a conductive filament (CF). Because of the weak diffusion/migration stopping power of Ti for Cu, the resulting Cu CF is of a cylindrical form instead of a conical form with the former being very difficult to rupture as shown in FIG. 3. Cu ions 305 from electrode 310 diffuse into the Ti of electrode 312 preventing conductor 300 from forming a conductive via connection of a more or less conical shape.

In addition, a 5Ω cylindrical filament of L=25 nm, assuming bulk Cu resistivity, would require a diameter of 11 nm. Since resistivity of the filament is larger than bulk Cu, its diameter would have to be significantly larger than 11 nm which is unlikely. Thus, multiple filaments may be provided. Nevertheless, the diameter of the filament is much smaller than the top electrode.

The second set transition leads to a dramatic decrease of R_{ON} by a factor 10⁵. To ascertain the nature of the electrical connection, the temperature coefficient of resistance α of the CF was measured and unusually high values, typically α=0.04K⁻¹ were obtained, which is 10× larger than α for bulk Cu, α=0.0039K⁻¹, or for Cu CF in Cu/TaOₓ/Pt, α=0.0033K⁻¹ and 40× higher than α for oxygen vacancy defects CF, α=0.001K⁻¹. The secondary set from R_{ON}(1) to R_{ON}(2) may be attributed to a phase transformation and does not depend on bias polarity for the formation of the conductor.

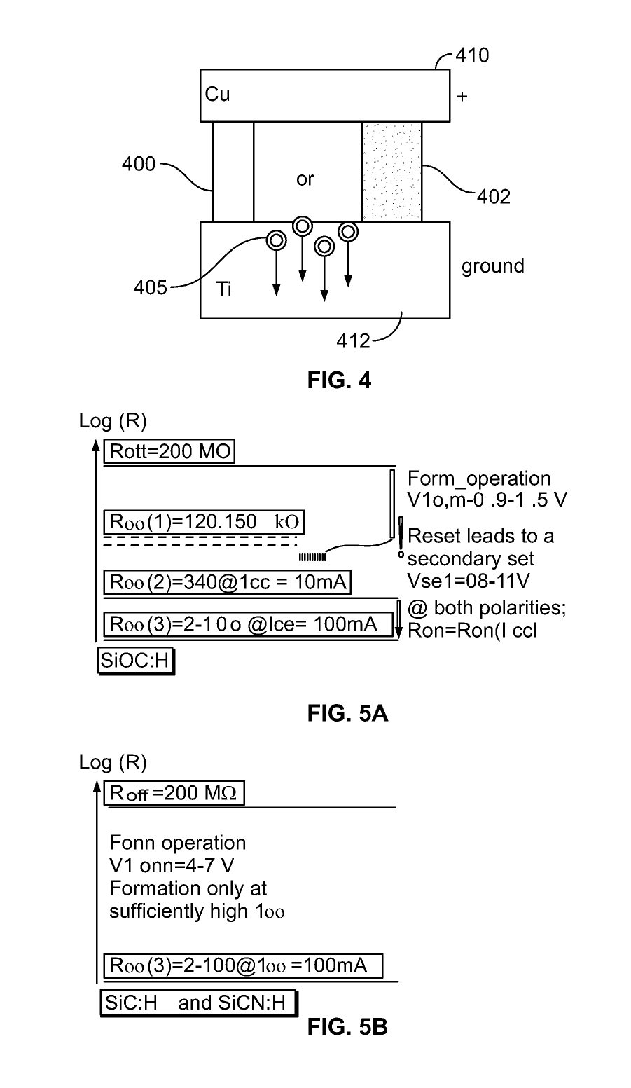

As shown in FIG. 4, the second transition, in some circumstances, may be caused by formation of a Cu conductor 400 which may be a conductive filament (CF). Other conductors 402 may be formed as well. Because of the weak diffusion/migration stopping power of Ti for Cu, the resulting Cu CF is of a cylindrical form instead of a conical form with the former being very difficult to rupture. Cu ions 405 from electrode 410 diffuse into the Ti of electrode 412 weakening the base of the filament at the Ti electrode interface and thus preventing conductor 400 and or conductor 402 from forming a cone or conical shape.

Structures with SiC:H (same metal electrodes) show different behavior, but result in the same low resistivity state R_{ON}(2). They require high Vₛₑₜ=3-4V and display volatile behavior at low I_{cc} values.

At higher I_{cc} they set into a stable and very low R_{ON}≈5Ω, which may constitute a 1-level PROM. Similarly, devices with SiCN:H may set permanently at high I_{cc} currents (50-100 mA) and display a very low final resistance of about 10Ω.

FIGS. 5A and 5B provide a comparison of low dielectrics SiOC:H with SiC:H and SiCN:H. Because of a low density, Cu can diffuse through SiOC:H readily. But the low density of SiOC:H cannot support a high-density Cu filament. The resulting CF is highly resistive and conduction is based on electron tunneling from Cu atom to Cu atom. At high currents, the Cu electrode at the contact is heated by providing a large number of Cu atoms beyond the electrochemical reaction Cu˜Cu⁺e⁻. The Cu ion electromigration enables the formation of a high-density Cu CF. In case of SiC:H and SiCN:H, strong fields are needed to break the bonds of the matrix. Cu can move only when some sort of vacancy or defect has been created by high electric fields. It has been shown [Y Fan, S. King, J. Bielefeld, M. Orlowski Characterization of Porous BEOL Dielectrics for Resistive Switching, ECS Trans. 2016, v 72(2), p. 35-50] that porous materials will be able to form highly resistive Cu filaments.

In other embodiments, the present invention forms an electrical connection between the metal layers by charge defects of the dielectric layer. One such defect is oxygen vacancy. For example, in Ta₂O₅ it is easy to ionize an oxygen atom to form O²⁻ ion (doubly negative oxygen ion), which will be dislodged from the Ta₂O₅ matrix and leaves a vacancy (symbol V_{O}) behind. It is known that such vacancies agglomerate. Such filamentary agglomaration will form a conductive filament consisting of oxygen vacancies between two metal layers even in a Pt/TiO₂/Pt cell.

A Pt/TiO₂/Pt cell has no active electrode just two inert ones (Platinum). Under an electric field, an oxygen ion will be dislodged leaving an oxygen vacancy behind or a substochiometric titanium oxide TiOₓ with x<2. Thus, while TiO₂ is insulating, the TiOₓ is highly conductive. Accordingly, in this embodiment, no conductive filament is formed. Instead, the insulating TiO₂ changes to a conductive phase to create an electrical path in the dielectric.

In other embodiments, using the techniques described above, the present invention provides a memory device 100 as shown in FIGS. 1 and 2 comprised of a first array made of one or more electrodes 112 extending along a first direction made from a predetermined material. Also provided is a second array of electrodes extending along a second direction made from a second material and comprised of one or more electrodes, such as electrode 114.

As is also shown, at the intersection defined by an electrode of the first array and an electrode of the second array, a two-terminal resistive memory cell 110 may be formed. One or more memory cells 110 may be formed or programmed at each intersection by one or more conductive paths between the electrodes in the manner described above.

The conductive path may be irreversible when a voltage or current is applied to the device. The conductive paths may have a first resistance or a second resistance wherein the second resistance is less than said first resistance.

As also described above, the conductive paths may be formed by a phase change in a dielectric disposed between the first and second electrodes, by charged point defects in a dielectric disposed between said first and second electrodes and/or by conductors formed by the material of one of the electrodes. The phase change refers in this context to changing the high resistivity phase to a low resistivity phase of the material. The conductive filamentary connections may be cylindrical in shape and other cross sectional shapes described above.

In yet other embodiments, the above teachings of the present invention may be applied to program a memory cell by applying a voltage or current to each intersection formed by the opposing electrodes. Such a memory cell may be in the form of a 2-bit memory cell that may be used in PROM and/or FPGA applications.

Usually, a memory cell is defined just after a manufacturing to be in the logical state 0 and is later programmed to a logical state 1. In case of resistive switching memory as described, the logic state 0, called also an OFF state, may be a highly resistive state, such as around 200 MOhm or larger. The memory cell may then be programmed to a low resistance state, or logic state 1, called also ON state, by forming a conductive path such as a filament in the dielectric connecting the two electrodes. Thus, conductive path formation amounts to programming the cell. In a preferred embodiment, the high resistance state may be called logic state 1 and the low resistance state may be called logic 0, with the reverse being applicable as well. Thus, each intersection formed by the arrays of electrodes may be selectively programmed to have a predetermined resistive state and, accordingly, act a memory cell. Moreover, in PROM applications, the programmed state cannot be erased back to the other state, such as the OFF state, because here conductive path or filament formation may be irreversible in certain embodiments as described above.

While the foregoing written description enables one of ordinary skill to make and use what is considered presently to be the best mode thereof, those of ordinary skill will understand and appreciate the existence of variations, combinations, and equivalents of the specific embodiment, method, and examples herein. The disclosure should therefore not be limited by the above described embodiments, methods, and examples, but by all embodiments and methods within the scope and spirit of the disclosure.

What is claimed is:

1. A memory device comprising:
a first array of first electrodes extending along a first direction made from a first material;
a second array of second electrodes extending along a second direction made from a second material;
a third dielectric material disposed between the first array of first electrodes and the second array of the second electrodes; and
a plurality of intersections defined by the first array and the second array, wherein each intersection defines a two-terminal resistive memory cell, said memory cell formed by a conductive path in the dielectric material between said first and second electrodes.

2. The device of claim 1 wherein said conductive path is irreversible when a voltage or current is applied to the device.

3. The device of claim 2 having a plurality of conductive paths, said paths having either having a first resistance or a second resistance, said second resistance is less than said first resistance.

4. The device of claim 3 wherein said conductive paths are formed by a phase change in a dielectric disposed between said first and second electrodes.

5. The device of claim 3 wherein said conductive paths are formed by charged point defects in a dielectric disposed between said first and second electrodes.

6. The device of claim 3 wherein said conductive paths are formed by conductive filaments formed by the material of one of said electrodes.

7. The device of claim 6, wherein said conductors have substantially consistent cross sections.

8. A method of forming an electrical connection in the metallization backend of an integrated circuit comprising steps of:
providing a first electrode made of a first material and adapted to function as a terminal;
providing a second electrode made of a second material and adapted to function as a terminal;
providing an insulator layer between said first and said second electrodes; and
applying a voltage or current to one of said electrodes to create an active electrode while said other electrode is grounded, said voltage or current causes ions consisting of the material of the ungrounded electrode to form a conductor that electrically connects said electrodes.

9. The method of claim 8 wherein said active electrode is copper, silver or nickel, and said grounded electrode includes inert metals such as platinum, iridium, tungsten, or rhodium.

10. The method of claim 8 wherein said conductor has a substantially consistent cross section.

11. The method of claim 10 wherein said conductor is irreversible when a subsequent voltage or current is applied.

12. A method of forming an electrical connection in the metallization backend of an integrated circuit comprising steps of:
providing a first array of electrodes made of a first material and said electrodes adapted to function as one or more terminals;
providing a second array of electrodes made of a second material and said electrodes adapted to function as one or more terminals;
providing a dielectric layer between said arrays;
arranging said arrays to form a plurality of intersections defined by said electrodes of said first array and said electrodes of said second array, wherein each intersection defines a two-terminal resistive memory cell; and
applying a voltage or current to one of said electrodes to create an active electrode while said other electrode is grounded, said voltage or current causes one or more conductive paths to form in said dielectric that electrically connect said electrodes to form said memory cells.

13. The method of claim 12 wherein said conductive path in said dielectric is irreversible when a subsequent voltage or current is applied.

14. The method of claim 13 wherein said conductive path is formed by a phase change in said dielectric.

15. The method of claim 13 wherein said conductive path is formed by charged point defects in said dielectric.

16. The method of claim 13 wherein said conductive path is formed by a conductor formed by the material of the ungrounded electrode.

17. The method of claim 14 wherein a first transition voltage or current pulse is applied to one or more of said first electrodes to create one or more active electrodes while one or more of said second electrodes are grounded, said voltage or current pulse causes one or more conductive paths to form to create one or more memory cells having a first resistance, said first resistance is lower than that of the dielectric; and applying a second transition voltage or current pulse to one or more of said active electrodes, said second transition voltage or current pulse creates a second resistance in said one or more conductive paths, to create one or more memory cells having a second resistance that is less than said memory cells having said first resistance.

18. The method of claim 15 wherein a first transition voltage or current pulse is applied to one or more of said first electrodes to create one or more active electrodes while one or more of said second electrodes are grounded, said voltage or current pulse causes one or more conductive paths to form to create one or more memory cells having a first resistance, said first resistance is lower than that of the dielectric; and applying a second transition voltage or current pulse to one or more of said active electrodes, said second transition voltage or current pulse creates a second resistance in said one or more conductive paths, to create one or more memory cells having a second resistance that is less than said memory cells having said first resistance.

19. The method of claim 16 wherein a first transition voltage or current pulse is applied to one or more of said first electrodes to create one or more active electrodes while one or more of said second electrodes are grounded, said voltage or current pulse causes one or more conductive paths to form to create one or more memory cells having a first resistance, said first resistance is lower than that of the dielectric; and applying a second transition voltage or current pulse to one or more of said active electrodes, said second transition voltage or current pulse creates a second resistance in said one or more conductive paths, to create one or more memory cells having a second resistance that is less than said memory cells having said first resistance.

20. The method of claim 19 wherein said conductor has a substantially consistent cross section.
